(19) United States
(12) Patent Application Publication
(10) Pub. No.: US 2008/0230252 A1
(43) Pub. Date: Sep. 25, 2008

(54) Printed micro coaxial cable

(76) Inventor: Keh-Chang Cheng, Taoyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/812,104

(22) Filed: Jun. 15, 2007

(30) Foreign Application Priority Data
Mar. 23, 2007 (TW) 096204728

(51) Int. Cl. H05K 9/00; H01B 9/02

(52) U.S. Cl. 174/105 R; 174/102 R; 174/350

(57) ABSTRACT

A printed micro coaxial cable has a first metal shield layer, a first insulative layer formed on the first metal shield layer, and a conductive layer printed on the first insulative layer. The conductive layer includes a plurality of conductive transmitters spaced from each other. Two conductive transmitters are defined as a transmission pair. A second insulative layer is formed on the conductive layer. A second metal shield layer is formed on the second insulative layer. The printed micro coaxial cable of the present invention is manufactured by means of printing, simplifying manufacture process and reducing cost.

### BACKGROUND OF THE INVENTION

1. Field of the Invention

The present invention relates to a printed micro coaxial cable, and particularly to a printed micro coaxial cable which simplifies manufacture process and reduces cost and which prevents from electromagnetic interference.

2. Related Art

A conventional micro coaxial cable (MCC) 90 is illustrated in FIG. 1, which includes a central wire 91 shrouded by an inner insulative coating 92, a metal shield 93 enveloping the insulative coating 92, and an outer insulative layer 94. FIGS. 2A and 2B partially show a process for manufacturing such a micro coaxial cable 90, which involves multiple procedures, including copper wire pumping and insulative layer coating etc. Moreover, assembly of the micro coaxial cable 90 and connectors is rather troublesome and wants a great deal of labor force, resulting in unsatisfactory cost efficiency. In addition, when the metal shield 93 of the micro coaxial cable 90 is cut and peeled, metal threads tend to remain, correspondingly introducing noise.

### SUMMARY OF THE INVENTION

An object of the present invention is to provide a printed micro coaxial cable which simplifies manufacture process and reduces cost.

Another object of the present invention is to provide a printed micro coaxial cable which avoids noise arising from remaining metal threads during assembly and decreases electromagnetic interference (EMI) and cross talk, thereby improving signal transmission.

The printed micro coaxial cable comprises a first metal shield layer, a first insulative layer formed on the first metal shield layer, and a conductive layer printed on the first insulative layer. The conductive layer includes a plurality of strip-like conductive transmitters spaced from each other. Two conductive transmitters are defined as a transmission pair. A second insulative layer is formed on the conductive layer. A second metal shield layer is formed on the second insulative layer. An outer insulative layer is further provided to envelop the second metal shield layer and the first metal shield layer.

### BRIEF DESCRIPTION OF THE DRAWINGS

FIG. 1 is a structural view of a convention micro coaxial cable.

FIG. 2A schematically shows a part of a manufacture process of the convention micro coaxial cable.

FIG. 2B is a flow chart of a manufacture process of the convention micro coaxial cable.

FIG. 3 is a cross-sectional view of a micro coaxial cable in accordance with a first embodiment of the present invention.

FIG. 4 is a structural diagram of a conductive layer of the micro coaxial cable in FIG. 3.

FIG. 5 is a cross-sectional view of a micro coaxial cable in accordance with a second embodiment of the present invention.

FIG. 6 is a cross-sectional view of a micro coaxial cable in accordance with a third embodiment of the present invention.

FIG. 7 is a cross-sectional view of a micro coaxial cable in accordance with a fourth embodiment of the present invention.

FIG. 8 is a cross-sectional view of a micro coaxial cable in accordance with a fifth embodiment of the present invention.

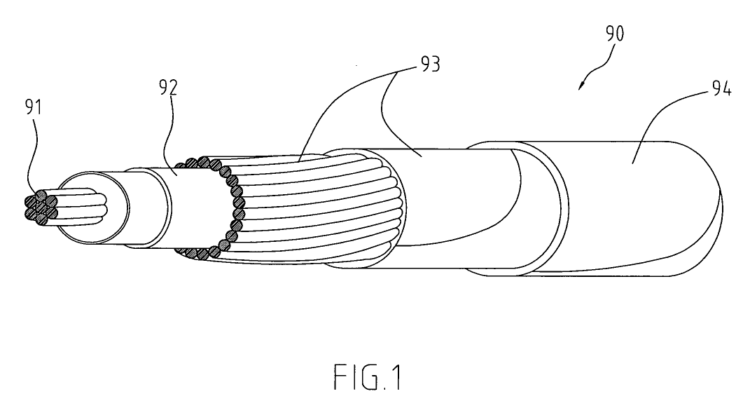

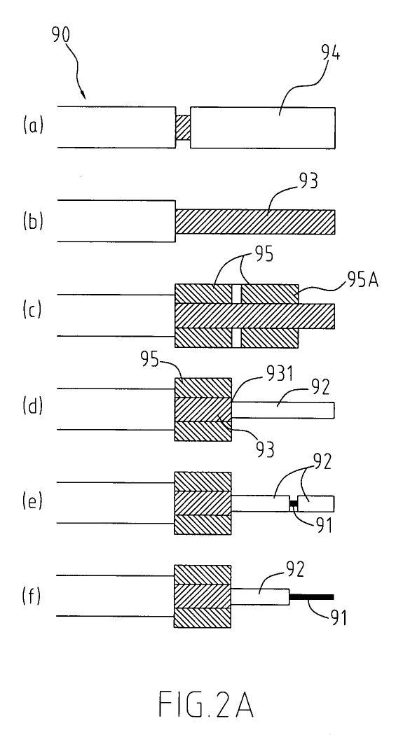

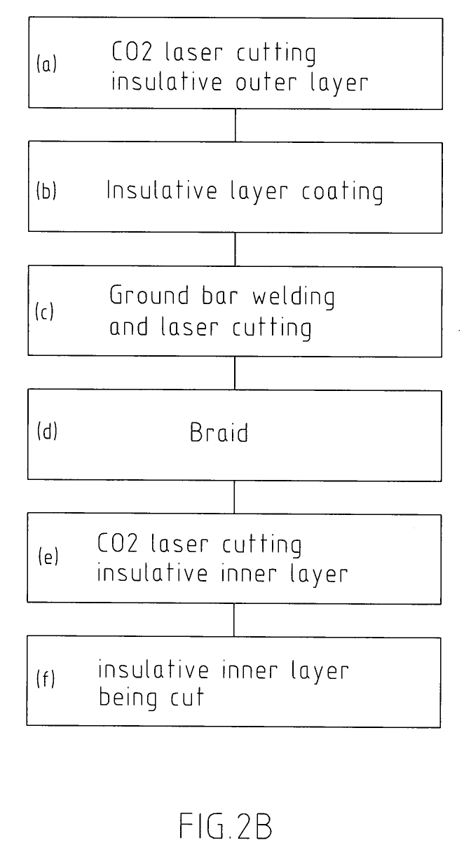

### DESCRIPTION OF THE PREFERRED EMBODIMENTS

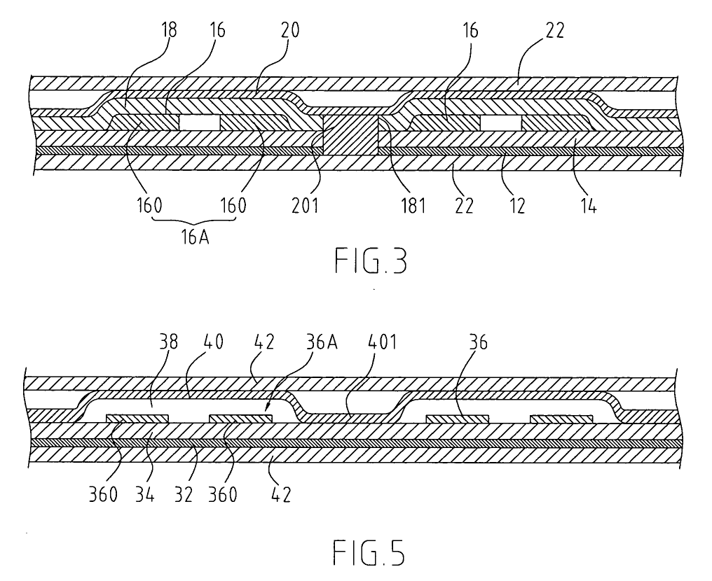

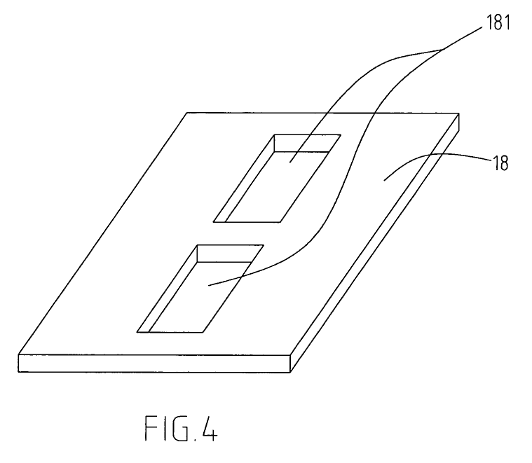

With reference to FIG. 3, a micro coaxial cable in accordance with a first embodiment of the present invention comprises a first metal shield layer 12, a first insulative layer 14 formed on the first metal shield layer 12, and a conductive layer 16 printed on the first insulative layer 14. The conductive layer 16 is formed by metal film printing, and includes a plurality of strip-like conductive transmitters 160 spaced from each other. Each two conductive transmitters 160 are defined as a transmission pair 16A. A second insulative layer 18 is formed on the conductive layer 16. As shown in FIG. 4, the second insulative layer 18 defines a plurality of through holes 181 which are respectively aligned with space between the transmission pairs 16A of the conductive layer 16. In some embodiments, the through holes 181 are through notches or circumferential through holes. The second insulative layer 18 extends to cover the transmission pairs 16A and connects with the first insulative layer 14 for enveloping the transmission pairs 16A. A second metal shield layer 20 is formed on the second insulative layer 18 by metal film printing. A shield portion 201 extends from the second metal shield layer 20 for corresponding to the through holes 181. The shield portion 201 extends through the through holes 181 and couples with the first metal shield layer 12. The second metal shield layer 20, the shield portion 201 and the first metal shield layer 12 shield the transmission pairs 16A of the conductive layer 16. The second metal shield layer 20 and the first metal shield layer 12 are commonly grounded and electrically connect with connectors (not shown). An outer insulative layer 22 is further provided to envelop the second metal shield layer 20 and the first metal shield layer 12 for insulating and strengthening.

Referring to FIG. 5, which shows a micro coaxial cable in accordance with a second embodiment of the present invention. The micro coaxial cable comprises a first metal shield layer 32, a first insulative layer 34 formed on the first metal shield layer 32, and a conductive layer 36 printed on the first insulative layer 34. The conductive layer 36 is formed by metal film printing, and includes a plurality of strip-like conductive transmitters 360 spaced from each other. Each two neighboring conductive transmitters 160 are defined as a transmission pair 36A. A second insulative layer 38 is formed on the conductive layer 36 by dielectric printing. The second insulative layer 38 is formed on the conductive transmitters 360 and the first insulative layer 34 in the units of respectively corresponding to the transmission pairs 36A for enveloping the transmission pairs 36A. A second metal shield layer 40 is formed on the second insulative layer 38 by metal film printing, and is made of the same material as the first metal shield layer 32. The second metal shield layer 40 has a sunken shield portion 401 corresponding to space between the transmission pairs 36A. The shield portion 401 extends to connect with the first insulative layer 34 to separate two neighboring transmission pairs 36A. The second metal shield layer 40, the shield portion 401 and the first metal shield layer 32 shield the transmission pairs 36A of the conductive layer 36. The second metal shield layer 40 and the first metal shield layer 32 are commonly grounded and electrically connect with connectors (not shown). An outer insulative layer 42 is further provided to envelop the second metal shield layer 40 and the first metal shield layer 32.

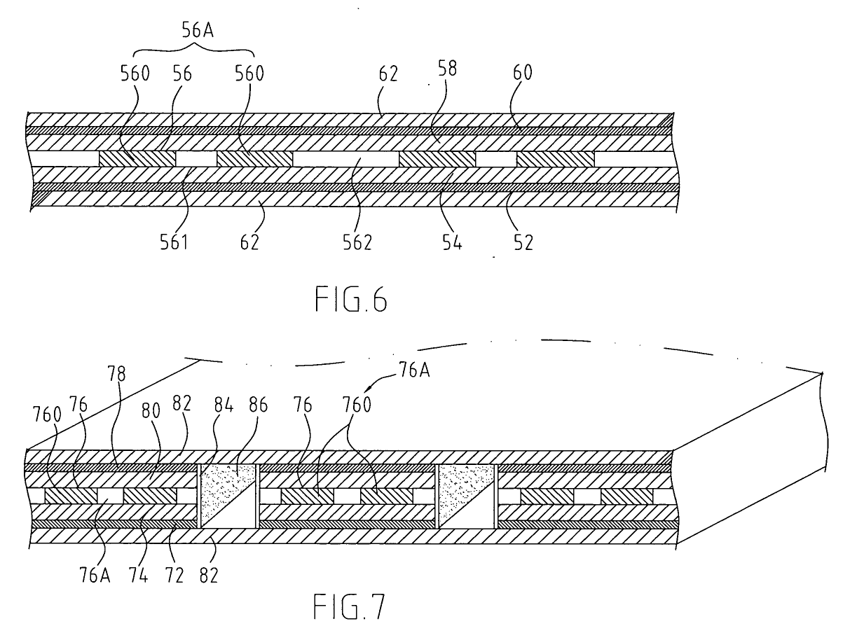

Referring to FIG. 6, a micro coaxial cable in accordance with a third embodiment of the present invention comprises a first metal shield layer 52, a first insulative layer 54 formed on the first metal shield layer 52, and a conductive layer 56 printed on the first insulative layer 54. The conductive layer 56 is formed by metal film printing, and includes a plurality of strip-like conductive transmitters 560 spaced from each other. Each two neighboring conductive transmitters 560 are defined as a transmission pair 56A. A second insulative layer 58 is formed on the conductive layer 56. A first space 561 is defined between two conductive transmitters 560 of each transmission pair 56A. A second space 562 is defined between two neighboring transmission pair 56A. The first space 561 and the second space 562 are both hollowed. That is, the first insulative layer 54 disconnect from the second insulative layer 58. A second metal shield layer 60 is formed on the second insulative layer 58 by metal film printing. The second metal shield layer 60 and the first metal shield layer 52 shield the transmission pairs 56A of the conductive layer 56. The second metal shield layer 60 and the first metal shield layer 52 are commonly grounded and electrically connect with connectors (not shown). An outer insulative layer 62 is further provided to envelop the second metal shield layer 60 and the first metal shield layer 52.

Referring to FIG. 7, a micro coaxial cable in accordance with a fourth embodiment of the present invention comprises a first metal shield layer 72 having a plurality of metal plates spaced apart from each other, a first insulative layer 74 formed on the first metal shield layer 72, and a conductive layer 76 printed on the first insulative layer 74. The conductive layer 76 is formed by metal film printing, and includes a plurality of strip-like conductive transmitters 760 spaced from each other. Each two neighboring conductive transmitters 760 are defined as a transmission pair 76A. A second insulative layer 78 is formed on the conductive layer 76. A second metal shield layer 80 is formed on the second insulative layer 78 by metal film printing. An outer insulative layer 82 is further provided to envelop the second metal shield layer 80 and the first metal shield layer 72. Side insulative layers 84 are provided to envelop sides of the transmission pairs 76A. Viewed from FIG. 7, the side insulative layers 84 connect with an upper portion and a lower portion of the outer insulative layer 82. Side shield layers 86 are formed on the side insulative layers 84 by injecting printing for shielding the side insulative layers 84. The second metal shield layer 80, the side shield layers 86 and the first metal shield layer 72 shield the transmission pairs 76A of the conductive layer 76. The second metal shield layer 80 and the first metal shield layer 72 are commonly grounded and electrically connect with connectors (not shown).

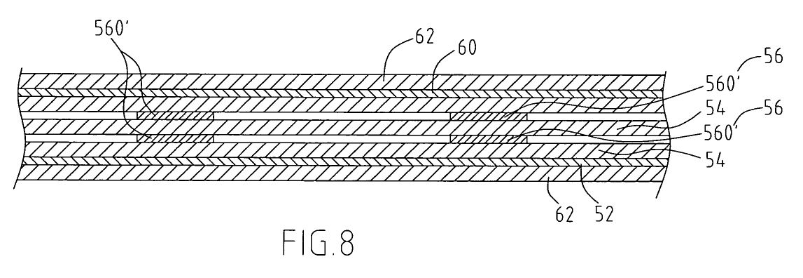

FIG. 8 schematically illustrates a micro coaxial cable in accordance with a fifth embodiment of the present invention. According to the third embodiment, each transmission pair 56A has conductive transmitters 560 juxtaposed in a horizontal plane. According to the fifth embodiment, two conductive layers 56′ are provided and are cascaded in two horizontal planes. Accordingly, the conductive transmitters 560′ of the conductive layers 56′ are arrayed in two horizontal planes. Each transmission pair 56A′ has a conductive transmitter 560′ in an upper position and a conductive transmitter 560′ in a lower position. Correspondingly, two first insulative layers are provided and are cascaded in two horizontal planes for respectively corresponding to the two conductive layers 56′.

The printed micro coaxial cable of the present invention is manufactured by means of printing, simplifying manufacture process and reducing cost. In addition, clearance between two wires of each transmission pair is reduced, enhancing coupling effect of the transmission pair, and further preventing from cross talk and electromagnetic interference, thereby improving signals transmission.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. A printed micro coaxial cable, comprising:
a first metal shield layer;
a first insulative layer formed on the first metal shield layer;
a conductive layer formed on the first insulative layer by printing, and including a plurality of conductive transmitters spaced from each other, each two conductive transmitters being defined as a transmission pair; and
a second insulative layer formed on the conductive layer.

2. The printed micro coaxial cable as claimed in claim 1, wherein the conductive layer is formed by metal film printing.

3. The printed micro coaxial cable as claimed in claim 1, wherein a second metal shield layer is formed on the second insulative layer by metal film printing.

4. The printed micro coaxial cable as claimed in claim 3, wherein the second insulative layer defines a plurality of through holes which are respectively aligned with space between the transmission pairs of the conductive layer, and wherein a shield portion extends from the second metal shield layer for corresponding to the through holes, the shield portions extending through the through holes and coupling with the first metal shield layer.

5. The printed micro coaxial cable as claimed in claim 1, wherein the second insulative layer extends to cover the transmission pairs and connects with the first insulative layer.

6. The printed micro coaxial cable as claimed in claim 1, wherein the second metal shield layer has a shield portion corresponding to space between the transmission pairs.

7. The printed micro coaxial cable as claimed in claim 6, wherein the shield portion connects with the first insulative layer.

8. The printed micro coaxial cable as claimed in claim 1, wherein the second metal shield layer and the first metal shield layer are commonly grounded and electrically connect with connectors.

9. The printed micro coaxial cable as claimed in claim 1, wherein the second insulative layer is formed by dielectric printing.

10. The printed micro coaxial cable as claimed in claim 9, wherein the second insulative layer is formed on the conductive transmitters and the first insulative layer in the units of respectively corresponding to the transmission pairs for enveloping the transmission pairs.

11. The printed micro coaxial cable as claimed in claim 1, wherein the second metal shield layer is made of the same material as the first metal shield layer.

12. The printed micro coaxial cable as claimed in claim 1, wherein an outer insulative layer is further provided to envelop the second metal shield layer and the first metal shield layer.

13. The printed micro coaxial cable as claimed in claim 12, wherein side insulative layers are provided to envelop sides of the transmission pairs, and connect with the outer insulative layer.

14. The printed micro coaxial cable as claimed in claim 1, wherein side shield layers are formed on the side insulative layers by printing for shielding the side insulative layers.

15. A printed micro coaxial cable comprising:
first metal shield layers being cascaded;
a first insulative layer being formed on the first metal shield layers;
conductive layers being cascaded and formed on the first insulative layer by printing, and including a plurality of conductive transmitters spaced from each other, each two conductive transmitters being defined as a transmission pair, each transmission pair having a conductive transmitter in an upper position and a conductive transmitter in a lower position; and
a second insulative layer being formed on the conductive layer.

16. The printed micro coaxial cable as claimed in claim 15, wherein the conductive layer is formed by metal film printing.

17. The printed micro coaxial cable as claimed in claim 15, wherein a second metal shield layer is formed on the second insulative layer by metal film printing.

18. The printed micro coaxial cable as claimed in claim 15, wherein an outer insulative layer is further provided to envelop the second metal shield layer and the first metal shield layer.
